(19) United States
(12) Patent Application Publication
(10) Pub. No.: US 2009/0162794 A1
(43) Pub. Date: Jun. 25, 2009

(54) METHOD FOR FABRICATING SEMICONDUCTOR DEVICE

(75) Inventor: Jin-Ki JUNG, Ichon-shi (KR)

Correspondence Address: TOWNSEND AND TOWNSEND AND CREW, LLP, TWO EMBARCADERO CENTER, EIGHTH FLOOR, SAN FRANCISCO, CA, 94111-3834, US

(73) Assignee: Hynix Semiconductor Inc., Ichon-shi (KR)

(21) Appl. No.: 12/165,407

(22) Filed: Jun. 30, 2008

(30) Foreign Application Priority Data
Dec. 21, 2007 (KR) 10-2007-0135220

(51) Int. Cl. H01L 21/302

(52) U.S. Cl. 430/319

(57) ABSTRACT

A method for fabricating a semiconductor device is provided. The method includes forming an even number of first hard mask patterns over an etch target layer, forming sacrificial patterns on sidewalls of the first hard mask patterns and forming second hard mask patterns on sidewalls of the sacrificial patterns. The second hard mask patterns are formed to have a first space between the first hard mask patterns. The etch target layer is etched by using the first and the second hard mask patterns.

### CROSS-REFERENCE TO RELATED APPLICATIONS

The present invention claims priority of Korean patent application number 10-2007-0135220, filed on Dec. 21, 2007, which is incorporated by reference in its entirety.

### BACKGROUND OF THE INVENTION

The present invention relates to a method for fabricating a semiconductor device, and more particularly, to a method for fabricating a semiconductor device, which is capable of forming an even number of micro patterns.

In accordance with an integration of semiconductor devices, a method for forming micro patterns with a line width under 40 nm is needed. However, it is hard to form the above described micro patterns with conventional exposure apparatuses. As one approach to overcoming such a limitation, a double exposure and etch technology (DEET) has been suggested.

However, when a DEET process is applied to form micro patterns, overlay accuracy between a first photoresist pattern and a second photoresist pattern may be low. Therefore, the micro patterns may be asymmetry and a critical dimension (CD) of the micro patterns may have a bad uniformity. Furthermore, a bottom anti-reflective coating (BARC) pattern may be non-uniformly formed while the second photoresist pattern is formed because of a bad topology of an anti-reflective pattern formed between the first photoresist pattern and the second photoresist pattern.

In order to overcome the above described limitations, a space patterning technology (SPT) process has been suggested. The SPT process includes an SPT negative scheme and an SPT positive scheme. When the SPT negative scheme is performed, a bottom portion under a photoresist pattern remains. When the SPT positive scheme is performed, a bottom portion exposed by a photoresist pattern remains.

FIGS. 1A and 1B illustrate cross-sectional views of a conventional method for fabricating a semiconductor device using a SPT negative scheme.

Referring to FIG. 1A, an etch target layer 12 is formed over a substrate 11, and then a first hard mask layer 13 is formed over the etch target layer 12. N number of photoresist patterns 14 are formed over the first hard mask layer 13. As shown, a ratio of a width of a photoresist pattern 14 to a width of a space between two photoresist patterns 14 is approximately 1:3.

The first hard mask layer 13 is etched by using the photoresist patterns 14 as an etch barrier, thereby forming first hard mask patterns 13A. A sacrificial pattern (not shown) is formed on the sidewalls of the first hard mask patterns 13A, and then a second hard mask layer (not shown) is formed over the resultant structure including the sacrificial patterns.

After forming the hard mask layer, a chemical mechanical polishing (CMP) process is performed on a surface of the sacrificial layer. Thus, a sacrificial pattern 15 and a second hard mask pattern 16 are formed. Each line width of the sacrificial pattern 15 and the second hard mask pattern 16 is the same as that of the first hard mask pattern 13A, as shown in FIG. 1B.

Although it is not shown, the etch target layer 12 is etched by using the first hard mask pattern 13A and the second hard mask pattern 16 as an etch barrier, thereby forming etch target patterns (not shown) which are micro patterned. However, when the above described SPT negative scheme is applied for forming the etch target pattern with the N number of the photoresist patterns 14, the number of the etch target patterns becomes ‘2N−1’. That is, an odd number of the etch target patterns is formed.

When an even number of etch target patterns, such as 32 or 34 of strings in a cell of nonvolatile memory devices, is needed, an additional mask process and etch process must be performed since a etch target pattern must be removed. That is, steps of process for forming the etch target patterns is increased. Thus, a method which can simplify steps of process and form an even number of etch target patterns is needed.

### SUMMARY OF THE INVENTION

An embodiment of the present invention is relates to a method for fabricating a semiconductor device, which is capable of forming an even number of micro patterns.

In accordance with an aspect of the present invention, there is provided a method for fabricating a semiconductor device. The method includes forming an even number of first hard mask patterns over an etch target layer, forming sacrificial patterns on sidewalls of the first hard mask patterns, forming second hard mask patterns on sidewalls of the sacrificial patterns, wherein the second hard mask patterns are formed to have a first space between the first hard mask patterns, and etching the etch target layer by using the first and the second hard mask patterns.

### BRIEF DESCRIPTION OF THE DRAWINGS

FIGS. 1A and 1B illustrate cross-sectional views of a conventional method for fabricating a semiconductor device using a SPT negative scheme.

FIGS. 2A to 2F illustrate cross-sectional views of a method for fabricating a semiconductor device in accordance with an embodiment of the present invention.

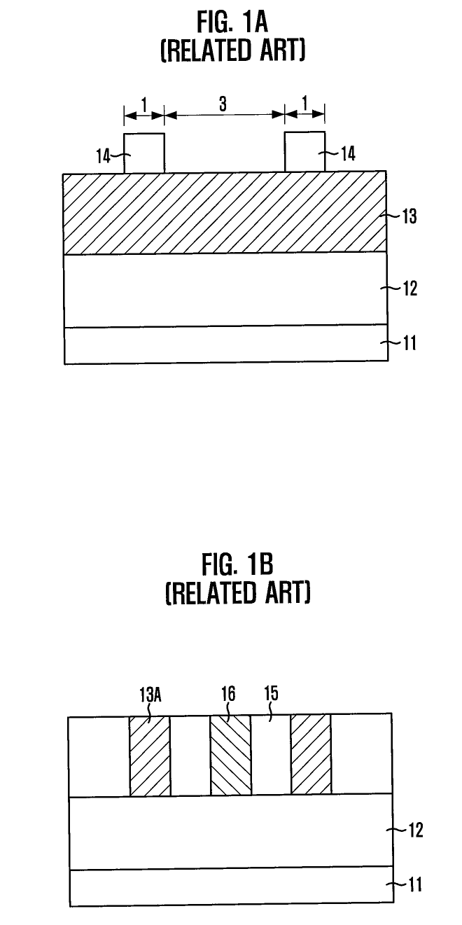

### DESCRIPTION OF SPECIFIC EMBODIMENTS

Hereinafter, a method for fabricating a semiconductor device in accordance with the present invention will be described in detail with reference to the accompanying drawings.

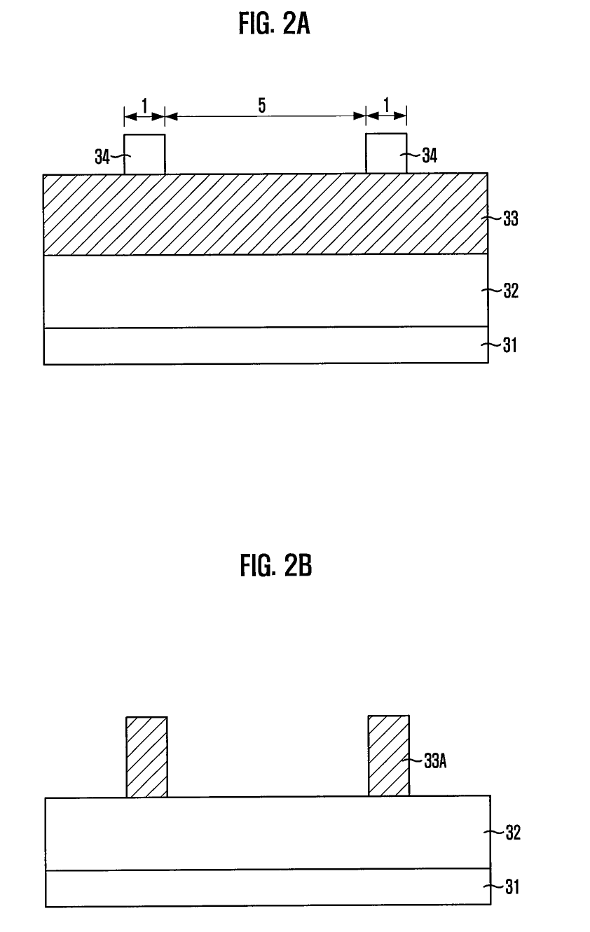

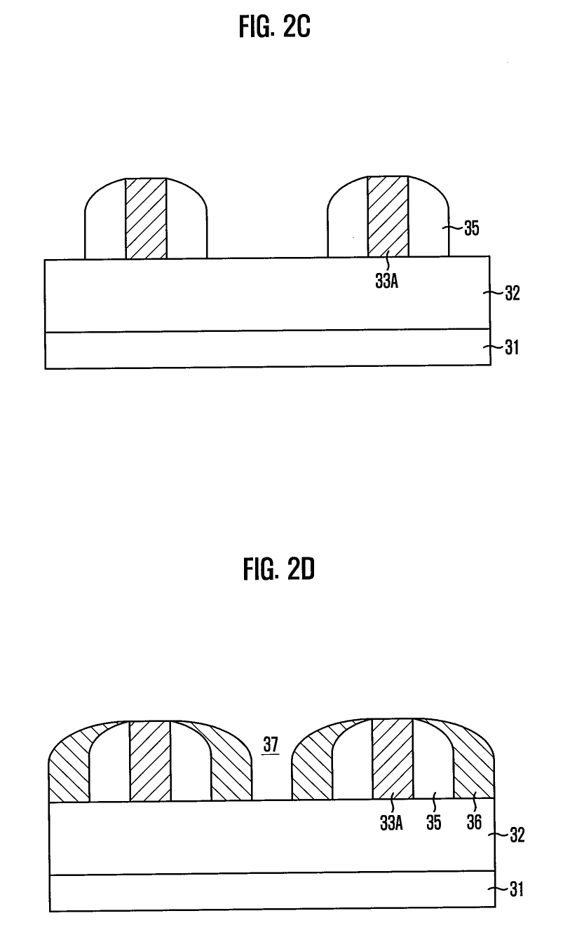

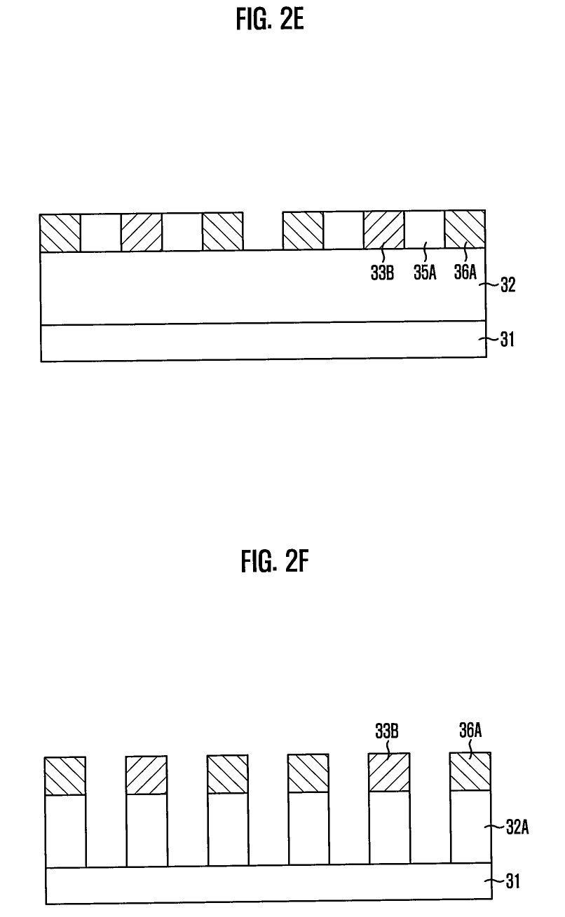

FIGS. 2A to 2F illustrate cross-sectional views of a method for fabricating a semiconductor device in accordance with an embodiment of the present invention.

Referring to FIG. 2A, an etch target layer 32 is formed over a substrate 31, and then a first hard mask layer 33 is formed over the etch target layer 32. Herein, the etch target layer 32 may be a hard mask layer which is patterned for etching a bottom layer. For example, when a gate conductive layer is formed under the etch target layer 32, the etch target layer 32 may act as a gate hard mask layer. The etch target layer 32 includes an oxide layer or a nitride layer.

When the etch target layer 32 includes the oxide layer, the first hard mask layer 33 includes a polysilicon layer or a nitride layer. Furthermore, when the etch target layer 32 includes the nitride layer, the first hard mask layer 33 includes an oxide layer.

An even number of photoresist patterns 34 is formed over the first hard mask layer 33. A ratio of a width of a photoresist pattern 34 to a width of a space between two neighboring photoresist patterns 34 is approximately 1:5.

In accordance with the embodiment of the present invention, two photoresist patterns 34 will be described hereinafter, as an example. In one embodiment, if the first hard mask layer 33 is not sufficiently etched by using the photoresist patterns 34, an amorphous carbon layer and a silicon oxynitride (SiON) layer may be additionally formed under the photoresist patterns 34.

Referring to FIG. 2B, the first hard mask layer 33 is etched by using the photoresist patterns 34 as an etch barrier, thereby forming a plurality of hard mask patterns 33A. The etching of the first hard mask layer 33 is performed by a plasma etching process. Then, the photoresist patterns 34 are removed.

Referring to FIG. 2C, sacrificial patterns 35 are formed on both sidewalls of the first hard mask patterns 33A. To form the sacrificial patterns 35 having a spacer shape, a sacrificial layer (not shown) is formed over the resultant structure including the first hard mask patterns 33A, and then a blanket etching process is performed over the sacrificial layer.

The sacrificial patterns 35 should be formed of materials which have an etch selectivity with respect to the first hard mask patterns 33A in the same etching gas. For example, when the first hard mask patterns 33A include a polysilicon layer or a nitride layer, the sacrificial patterns 35 include an oxide layer, and when the first hard mask patterns 33A include an oxide layer, the sacrificial patterns 35 include a polysilicon layer or a nitride layer.

Referring to FIG. 2D, second hard mask patterns 36 are formed on sidewalls of the sacrificial patterns 35. To form the second hard mask patterns 36 having a spacer shape, a second hard mask layer (not shown) is formed over the resultant structure including the sacrificial patterns 35, and then a unisotropical etching process is performed on the second hard mask layer.

When the sacrificial patterns 35 and the second hard mask patterns 36 are formed at both sides of the first hard mask pattern 33A,a space 37 with a line width of “1” (See FIG. 2A) is formed between two neighboring first hard mask patterns 33A covered by the sacrificial patterns 35 and the second hard mask patterns 36. That is, in one embodiment, the space 37 may be formed having the line width as the same as a line width of the first hard mask pattern 33A. In such an embodiment, the first hard mask pattern 33A, the second hard mask pattern 36, the sacrificial pattern 35 and the space 37 may have the same line width.

Referring to FIG. 2E, a planarization process is performed on the resultant structure including the second hard mask patterns 36. The planarization process may be a chemical mechanical polishing (CMP) process or an etch back process. Thus, after performing the planarization process, etched first hard mask patterns 33B, etched sacrificial patterns 35A and etched second hard mask patterns 36A are formed.

Referring to FIG. 2F, the etch target layer 32 is etched by using the etched first hard mask patterns 33B and the etched second hard mask patterns 36A as an etch barrier. In order to etch the etch target layer 32, the etched sacrificial patterns 35A may need to be removed. The etched sacrificial patterns 35A may be etched with a dry etching process. The dry etching process may be a plasma etching process using a gas having a high ratio of carbon to fluorine. The gas having the high ratio of carbon to fluorine may include C₂F₆ or C₄F₈.

The reason using the gas having the high ratio of carbon to fluorine is to increase an etch selectivity of the etched sacrificial patterns 35A to the etched first hard mask patterns 33B and the etched second hard mask patterns 36A. Moreover, as another example, a portion of the etched sacrificial patterns 35A is etched by an wet etching process and the remaining portion of the etched sacrificial patterns 35A is etched by a dry etching process. Furthermore, when the sacrificial patterns 35 and the etch target layer 32 are formed of the same material, the etch target layer 32 may be also etched during the etching of the etched sacrificial patterns 35A.

As described above, the ratio of the width of a photoresist pattern to the width of the space between two neighboring photoresist patterns is set up to 1:5 in order to form an even number of micro patterns in accordance with the embodiment of the present invention. When the ratio of the width of the photoresist pattern to the width of the space between the photoresist patterns is set up to 1:5, a space with a line width of “5” (See FIG. 2A) is formed between two first hard patterns 33A patterned by the photoresist patterns 34.

Two second hard mask patterns 36A is formed in the space. Thus, etch target patterns 32A are formed by using the etched first hard mask patterns 33B and the etched second hard mask patterns 36A, wherein the number of the etch target patterns 32A is 4. That is, an even number of micro patterns is formed.

Although etch target patterns are formed with another method as far as a ratio of a width of a pattern to a width of a space between two neighboring patterns is set to 1:(5+4N), an even number of etch target patterns can be formed. Herein, N is 0 or a natural number ranging from 1 to 100.

The present invention is not limitative to a method for forming micro patterns and is applicable to a method for forming an even number of contact holes. Furthermore, the present invention is also applicable to a damascene etching process.

While the present invention has been described with respect to the specific embodiments, the above embodiments of the present invention are illustrative and not limitative. It will be apparent to those skilled in the art that various changes and modifications may be made without departing from the spirit and scope of the invention as defined in the following claims.

What is claimed is:

1. A method for fabricating a semiconductor device, the method comprising:
forming an even number of first hard mask patterns over an etch target layer;
forming sacrificial patterns on sidewalls of the first hard mask patterns;
forming second hard mask patterns on sidewalls of the sacrificial patterns, wherein the second hard mask patterns are formed to have a first space between the first hard mask patterns; and
etching the etch target layer by using the first and the second hard mask patterns.

2. The method of claim 1, wherein a ratio of a width of the first hard mask pattern to a width of a space between two neighboring first hard mask patterns is approximately 1:5.

3. The method of claim 1, wherein a ratio of a width of the first hard mask pattern to a width of a space between two neighboring first hard mask patterns is approximately 1:(5+4N).

4. The method of claim 1, wherein the first hard mask pattern and the second hard mask pattern have the same line width.

5. The method of claim 1, wherein the first hard mask patterns, the second hard mask patterns, the sacrificial patterns and the first space have the same line width.

6. The method of claim 1, wherein the forming of the sacrificial patterns on the sidewalls of the first hard mask patterns comprises:
forming a sacrificial layer over a resultant structure having the first hard mask patterns; and
performing a blanket etching process on the sacrificial layer, thereby forming the sacrificial patterns.

7. The method of claim 1, wherein the forming of the second hard mask patterns comprises:
forming a second hard mask layer over a resultant structure having the first hard mask patterns and the sacrificial patterns; and
performing a blanket etching process on the second hard mask layer to form the second hard mask patterns.

8. The method of claim 3, wherein N is 0 or a natural number ranging from 1 to 100.
